(19) United States
(12) Patent Application Publication
(10) Pub. No.: US 2026/0040429 A1
(43) Pub. Date: Feb. 5, 2026

(54) POWER STAGE PACKAGE AND MANUFACTURING METHOD THEREOF, VOLTAGE REGULATING MODULE AND ELECTRONIC DEVICE

(71) Applicant: Ark HDPS Semiconductor Pte. LIMITED., Singapore (SG)

(72) Inventor: Yi-Cheng Lin, Hsinchu City (TW)

(73) Assignee: Ark HDPS Semiconductor Pte. LIMITED., Singapore (SG)

(21) Appl. No.: 19/260,291

(22) Filed: Jul. 4, 2025

(30) Foreign Application Priority Data
Jul. 30, 2024 (CN) 202411039868.2

(51) Int. Cl. H05K 1/02; H05K 1/11; H05K 3/28; H05K 3/34

(52) U.S. Cl. CPC H05K 1/0209; H05K 1/115; H05K 3/284; H05K 3/3415; H05K 2201/09227; H05K 2201/09618; H05K 2201/10166; H05K 2201/10522; H05K 2201/10545

(57) ABSTRACT

A power stage includes a PCB; two groups of transistors, where a first electrode of the low-side transistor is connected to a second electrode of the high-side transistor, a first via hole and a second trace; a first packaging layer covering the low-side transistor; a second packaging layer covering the high-side transistor; an exposed first redistribution layer, including a first redistribution portion covering a portion of a first side surface of the first package layer; a second redistribution portion covering a portion of a second side surface of the first package layer; the third redistribution part covering a portion of a third side surface of the second package layer; the fourth redistribution portion covering a portion of a fourth side surface of the second package layer; the fifth redistribution portion covering a portion of a fourth side surface of the second package layer away from the surface of the PCB.

### BACKGROUND OF THE INVENTION

### 1. Field of the Invention

The present disclosure relates to the field of power devices, and more particularly to a power stage package and a manufacturing method thereof, a voltage regulator module, and an electronic device.

### 2. Description of the Prior Art

A Voltage Regulator Module (VRM) provides an appropriate supply voltage for a processor. Since the VRM can adjust the supply voltage, the same motherboard can support processors requiring different supply voltages.

A voltage regulator module generally includes a power stage circuit and a control integrated circuit (IC).

### SUMMARY OF THE INVENTION

In the related art, packaged power stage circuits have relatively high resistance and poor heat dissipation. In view of this, the present disclosure provides the following technical solutions.

According to one aspect of an embodiment of the present disclosure, a power stage package is provided and includes: a printed circuit board including a first wiring layer, a second wiring layer, and an insulating layer disposed between the first wiring layer and the second wiring layer; two groups of transistors, each group of transistors including a low-side transistor disposed on a first side of the printed circuit board, and a high-side transistor disposed on a second side of the printed circuit board opposite to the first side, wherein a first electrode of the low-side transistor is electrically coupled to a second electrode of the high-side transistor through a first trace in the first wiring layer, a first via penetrating the insulating layer, and a second trace in the second wiring layer; a first package layer disposed on the first side of the printed circuit board and covering the low-side transistor; a second package layer disposed on the second side of the printed circuit board and covering the high-side transistor; and an exposed first redistribution layer configured to receive an input signal. The first redistribution layer includes: a first redistribution portion covering a portion of a first side surface of the first package layer; a second redistribution portion covering a portion of a second side surface of the first package layer; a third redistribution portion covering a portion of a third side surface of the second package layer, wherein the first redistribution portion is electrically coupled to the third redistribution portion through a third trace in the first wiring layer, a second via penetrating the insulating layer, and a fourth trace in the second wiring layer; a fourth redistribution portion covering a portion of a fourth side surface of the second package layer, wherein the second redistribution portion is electrically coupled to the fourth redistribution portion through a fifth trace in the first wiring layer, a third via penetrating the insulating layer, and a sixth trace in the second wiring layer; and a fifth redistribution portion covering a portion of a surface of the second package layer away from the printed circuit board, adjacent to the third and fourth redistribution portions, and connected to a first electrode of the high-side transistor in each transistor group through a fourth via penetrating the second package layer.

In some embodiments, two high-side transistors of the two groups of transistors are arranged along a first direction, and the first redistribution layer further includes: a sixth redistribution portion adjacent to the first redistribution portion and extending along the first direction; and a seventh redistribution portion adjacent to the second redistribution portion and extending along the first direction, wherein the first redistribution portion is sequentially connected to the third redistribution portion through the sixth redistribution portion, the third trace, the second via, the fourth trace, and the seventh redistribution portion.

In some embodiments, the first redistribution layer further includes: an eighth redistribution portion adjacent to the second redistribution portion and extending along the first direction; and a ninth redistribution portion adjacent to the fourth redistribution portion and extending along the first direction, wherein the second redistribution portion is sequentially connected to the fourth redistribution portion through the eighth redistribution portion, the fifth trace, the third via, the sixth trace, and the ninth redistribution portion.

In some embodiments, the first redistribution layer further includes at least one of the following: a tenth redistribution portion adjacent to the first redistribution portion and covering a portion of a surface of the first package layer away from the printed circuit board; and an eleventh redistribution portion adjacent to the second redistribution portion and covering another portion of a surface of the first package layer away from the printed circuit board.

In some embodiments, the power stage package further includes: an exposed second redistribution layer configured to receive a ground signal, covering a portion of a surface of the first package layer away from the printed circuit board, and connected to a second electrode of the low-side transistor through a fifth via penetrating the first package layer.

In some embodiments, the area of a portion of the surface of the second package layer away from the printed circuit board covered by the fifth redistribution portion is greater than half of the area of the surface of the second package layer away from the printed circuit board.

In some embodiments, the power stage package further includes: a driver disposed on the second side of the printed circuit board and covered by the second package layer, wherein the driver is connected to a gate of the high-side transistor through a seventh trace in the second wiring layer, and sequentially connected to a gate of the low-side transistor through a sixth via penetrating the insulating layer, a seventh via penetrating the first package layer, an eighth trace disposed on a surface of the first package layer away from the printed circuit board, and an eighth via penetrating the first package layer.

In some embodiments, the two high-side transistors of the two transistor groups are arranged along the first direction, and the driver and the two groups of transistors are arranged along a second direction perpendicular to the first direction and parallel to the surface of the printed circuit board.

In some embodiments, the driver is configured to perform time-division driving of the two groups of transistors.

According to another aspect of the present disclosure, a voltage regulation module is provided, including the power stage package of any of the foregoing embodiments.

According to still another aspect of the present disclosure, an electronic device is provided, including the voltage regulation module of any of the foregoing embodiments.

According to yet another aspect of the present disclosure, a method of manufacturing a power stage package is provided, including: providing a printed circuit board including a first wiring layer, a second wiring layer, and an insulating layer disposed between the first and second wiring layers; forming two groups of transistors, each group of transistors including a low-side transistor disposed on a first side of the printed circuit board, and a high-side transistor disposed on a second side of the printed circuit board opposite to the first side, wherein a first electrode of the low-side transistor is electrically coupled to a second electrode of the high-side transistor through a first trace in the first wiring layer, a first via penetrating the insulating layer, and a second trace in the second wiring layer; forming a first package layer and a second package layer, the first package layer disposed on the first side of the printed circuit board and covering the low-side transistor, the second package layer disposed on the second side of the printed circuit board and covering the high-side transistor; and forming an exposed first redistribution layer configured to receive an input signal, the first redistribution layer including: a first redistribution portion covering a portion of a first side surface of the first package layer; a second redistribution portion covering a portion of a second side surface of the first package layer; a third redistribution portion covering a portion of a third side surface of the second package layer, wherein the first redistribution portion is electrically coupled to the third redistribution portion through a third trace in the first wiring layer, a second via penetrating the insulating layer, and a fourth trace in the second wiring layer; a fourth redistribution portion covering a portion of a fourth side surface of the second package layer, wherein the second redistribution portion is electrically coupled to the fourth redistribution portion through a fifth trace in the first wiring layer, a third via penetrating the insulating layer, and a sixth trace in the second wiring layer; and a fifth redistribution portion covering a portion of a surface of the second package layer away from the printed circuit board, adjacent to the third and fourth redistribution portions, and connected to a first electrode of the high-side transistor in each transistor group through a fourth via penetrating the second package layer.

In some embodiments, the two groups of transistors are arranged along a first direction, and the first redistribution layer further includes: a sixth redistribution portion adjacent to the first redistribution portion and extending along the first direction; and a seventh redistribution portion adjacent to the third redistribution portion and extending along the first direction, wherein the first redistribution portion is sequentially connected to the third redistribution portion through the sixth redistribution portion, the third trace, the second via, the fourth trace, and the seventh redistribution portion.

In some embodiments, the first redistribution layer further includes: an eighth redistribution portion adjacent to the second redistribution portion and extending along the first direction; and a ninth redistribution portion adjacent to the fourth redistribution portion and extending along the first direction, wherein the second redistribution portion is sequentially connected to the fourth redistribution portion through the eighth redistribution portion, the fifth trace, the third via, the sixth trace, and the ninth redistribution portion.

In some embodiments, the first redistribution layer further includes at least one of the following: a tenth redistribution portion adjacent to the first redistribution portion and covering a portion of a surface of the first package layer away from the printed circuit board; and an eleventh redistribution portion adjacent to the second redistribution portion and covering another portion of a surface of the first package layer away from the printed circuit board.

In some embodiments, the area of a portion of the surface of the second package layer away from the printed circuit board covered by the fifth redistribution portion is greater than half of the area of the surface of the second package layer away from the printed circuit board.

The power stage package provided by the present disclosure has the first redistribution layer configured to receive an input signal exposed on the surface of the power stage package, where the first redistribution layer covers portions of two side surfaces of the first package layer and portions of two side surfaces of the second package layer. In addition, the first redistribution layer extends from a side surface (i.e., the third side surface) of the second package layer to a top surface of the second package layer, and further extends to another side surface (i.e., the fourth side surface) of the second package layer. Accordingly, the area of the first redistribution layer exposed on the package surface is large, which results in better heat dissipation and helps reduce resistance.

Other features, aspects, and advantages of the present disclosure will become apparent through the detailed description of exemplary embodiments with reference to the accompanying drawings.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The drawings form part of this specification and illustrate exemplary embodiments of the present disclosure, and together with the description serve to explain the principles of the present disclosure.

Referring to the drawings, the present disclosure can be better understood from the following detailed description. In the drawings:

FIG. 1 is a schematic circuit diagram illustrating a power stage package according to some embodiments of the present disclosure;

FIG. 2A is a side view illustrating a power stage package according to some embodiments of the present disclosure;

FIG. 2B is a top perspective view illustrating a partial structure of a power stage package according to some embodiments of the present disclosure;

FIG. 2C is a bottom perspective view illustrating a partial structure of a power stage package according to some embodiments of the present disclosure;

FIG. 3A is a cross-sectional schematic view taken along the A-A′ section shown in FIGS. 2B and 2C;

FIG. 3B is a cross-sectional schematic view taken along the B-B′ section shown in FIGS. 2B and 2C;

FIG. 4A is a top external appearance schematic view illustrating a power stage package according to some embodiments of the present disclosure;

FIG. 4B is a bottom external appearance schematic view illustrating a power stage package according to some embodiments of the present disclosure; and

FIG. 5 is a flowchart illustrating a manufacturing method of a power stage package according to some embodiments of the present disclosure.

### DETAILED DESCRIPTION

The following provides a detailed description of various exemplary embodiments of the present disclosure with reference to the accompanying drawings. The description of exemplary embodiments is illustrative only and is not intended to limit the present disclosure or its application or use in any way. The present disclosure may be implemented in many different forms and is not limited to the embodiments described herein. These embodiments are provided to ensure a thorough and complete understanding of the disclosure and to fully convey its scope to those skilled in the art. It should be noted that, unless otherwise specifically stated, the relative arrangement of components and steps, the composition of materials, numerical expressions, and numerical values described in these embodiments are to be understood as merely exemplary and not limiting.

As used in this disclosure, the terms “first,” “second,” and the like do not denote any order, quantity, or importance, but are used to distinguish different components. The terms “include” or “include” and similar expressions indicate that the elements before the term encompass the elements listed after the term but do not exclude the presence of other elements. Terms such as “above” or “below” merely describe relative positional relationships, which may change correspondingly when the absolute position of the described objects changes.

In the present disclosure, when describing a particular component located between a first component and a second component, there may or may not be an intermediate component between the particular component and the first or second component. When describing a particular component connected to other components, the particular component may be directly connected to the other components without intermediate components, or may be connected through intermediate components without direct connection.

All terms used in this disclosure (including technical and scientific terms) have the same meaning as commonly understood by those skilled in the art of the present disclosure unless otherwise specifically defined. It should also be understood that terms defined in general dictionaries are to be interpreted in a manner consistent with their meanings in the relevant technical context and not in an idealized or overly formal sense unless explicitly defined herein.

Known techniques, methods, and devices in relevant fields may not be described in detail herein; however, such techniques, methods, and devices should be regarded as a part of this specification as appropriate.

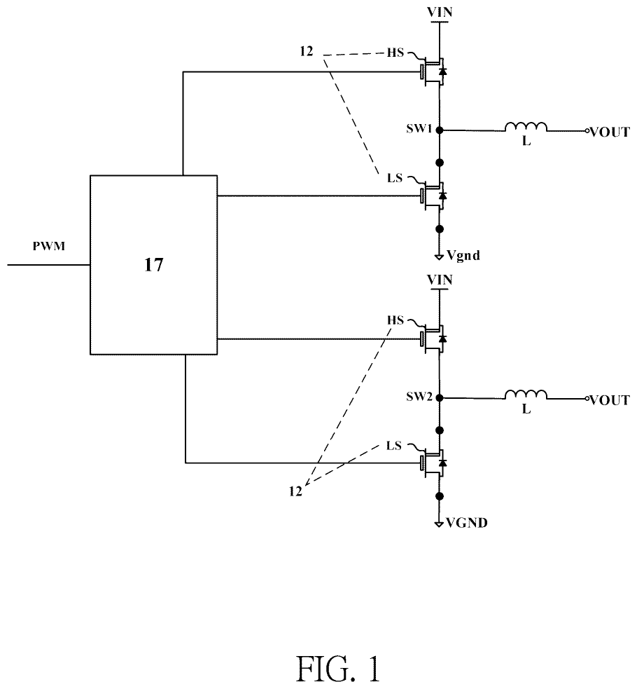

FIG. 1 is a schematic circuit diagram illustrating a power stage package according to some embodiments of the present disclosure.

Referring to FIG. 1, the power stage package includes two groups of transistors 12, each group of transistors 12 including a high-side transistor HS and a low-side transistor LS connected in series. In each group of transistors 12, the high-side transistor HS is connected between an input terminal VIN of the power stage package and the low-side transistor LS, and the low-side transistor LS is connected between the high-side transistor HS and a ground terminal VGND. In some embodiments, the high-side transistor HS and the low-side transistor LS can be metal oxide semiconductor field effect transistors (MOSFETs), such as N-type MOSFETS or P-type MOSFETS.

A driver 17 is connected respectively to the high-side transistor HS and the low-side transistor LS in each group of transistors 12. The driver 17 may control the high-side transistor HS and the low-side transistor LS in each group of transistors 12 to turn on or turn off according to pulse width modulation (PWM) signals from a control IC. Specifically, the driver 17 can be configured to turn off the low-side transistor LS when the high-side transistor HS is turned on, and to turn on the low-side transistor LS when the high-side transistor HS is turned off, to ensure that the high-side transistor HS and the low-side transistor LS in each group of transistors 12 are not turned on simultaneously, thereby avoiding a short circuit between the input terminal VIN and the ground terminal VGND.

In the two groups of transistors 12, nodes SW1 and SW2 located between the high-side transistor HS and the low-side transistor LS may be connected to the output terminal VOUT via inductors L, respectively.

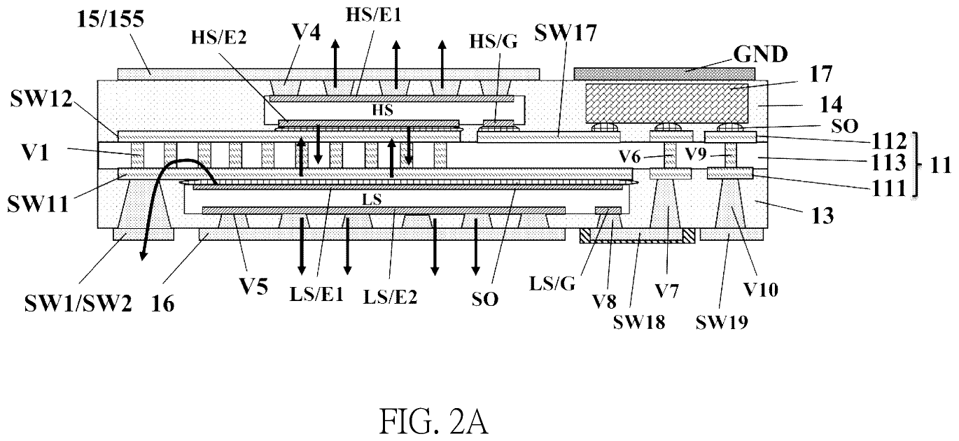

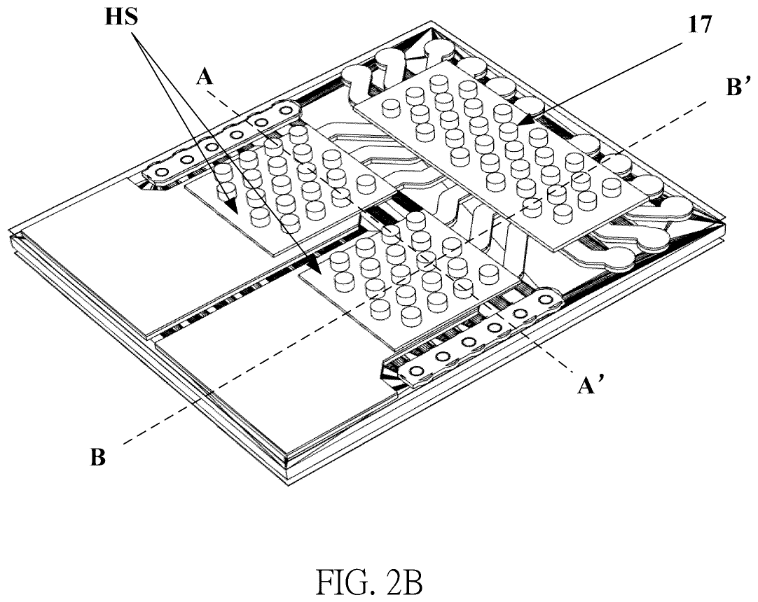

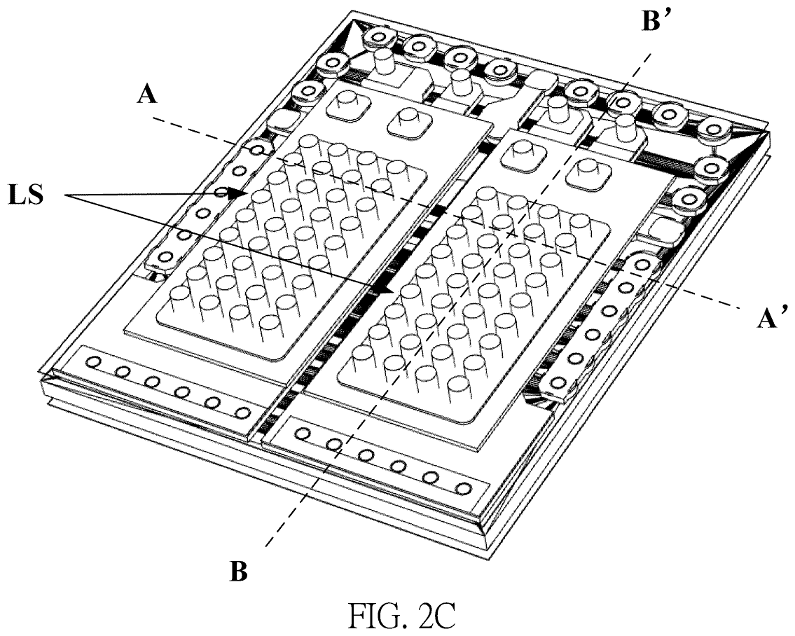

FIG. 2A is a side view illustrating a power stage package according to some embodiments of the present disclosure. FIG. 2B is a top view illustrating a power stage package according to some embodiments. FIG. 2C is a bottom view illustrating a power stage package according to some embodiments.

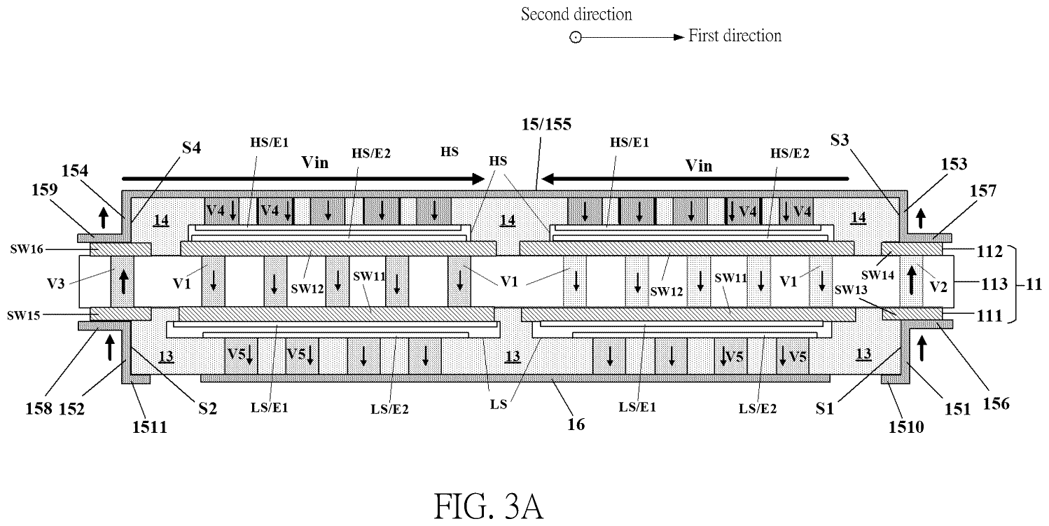

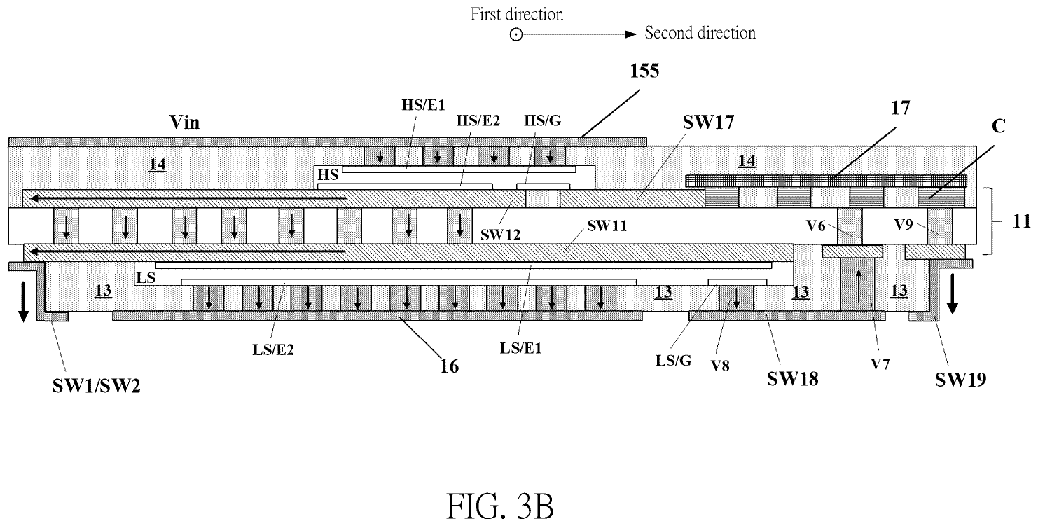

FIG. 3A is a schematic cross-sectional view taken along the A-A′ section shown in FIGS. 2B and 2C. FIG. 3B is a schematic cross-sectional view taken along the B-B′ section shown in FIGS. 2B and 2C.

Next, a description of the power stage package according to some embodiments of the present disclosure is provided with reference to FIGS. 2A to 2C and FIGS. 3A to 3B. Arrows in FIGS. 2A, 3A, and 3B indicate the electric current paths.

Referring to FIGS. 1, 2A, and 3A, the power stage package includes a printed circuit board (PCB) 11, two groups of transistors 12, a first package layer 13, a second package layer 14, and an exposed first redistribution layer (RDL) 15.

Referring to FIGS. 2A and 3A, the printed circuit board 11 includes a first wiring layer 111, a second wiring layer 112, and an insulating layer 113 disposed between the first wiring layer 111 and the second wiring layer 112. The first wiring layer 111 and the second wiring layer 112 are located on the upper and lower surfaces of the insulating layer 113, respectively.

The low-side transistor LS in each group of transistors 12 is disposed on the first side (the lower side in FIGS. 2A and 3A) of the printed circuit board 11, and the high-side transistor HS in each group of transistors 12 is disposed on the second side (the upper side in FIGS. 2A and 3A) opposite the first side of the printed circuit board 11. The first electrode E1 of the low-side transistor LS is electrically coupled to the second electrode E2 of the high-side transistor HS through a first trace SW11 in the first wiring layer 111, a first via V1 penetrating the insulating layer 113, and a second trace SW12 in the second wiring layer 112. The second electrode E2 of the low-side transistor LS is connected to the ground terminal VGND.

The first package layer 13 is disposed on the first side of the printed circuit board 11, covering the low-side transistor LS. The second package layer 14 is disposed on the second side of the printed circuit board 11, covering the high-side transistor HS. In some embodiments, the materials of the first package layer 13 and the second package layer 14 may be epoxy molding compound.

The exposed first redistribution layer 15 is configured to receive the input signal Vin, i.e., the input signal Vin is applied through the first redistribution layer 15 to the first electrode E1 of the high-side transistor HS. It should be understood that the entire exposed surface of the power stage package includes the surface of the first redistribution layer 15. For example, the material of the first redistribution layer 15 may include Cu, Ag, Sn, or Ni/Au alloys.

Referring to FIG. 3A, the first redistribution layer 15 includes a first redistribution portion 151, a second redistribution portion 152, a third redistribution portion 153, a fourth redistribution portion 154, and a fifth redistribution portion 155.

The first redistribution portion 151 covers a portion of the first side surface S1 of the first package layer 13, and the second redistribution portion 152 covers a portion of the second side surface S2 of the first package layer 13. Here, the first side surface S1 and the second side surface S2 are two opposite side surfaces of the first package layer 13.

The third redistribution portion 153 covers a portion of the third side surface S3 of the second package layer 14, and the fourth redistribution portion 154 covers a portion of the fourth side surface S4 of the second package layer 14. Similarly, the third side surface S3 and the fourth side surface S4 are two opposite side surfaces of the second package layer 14.

The first redistribution portion 151 is electrically coupled to the third redistribution portion 153 through a third trace SW13 in the first wiring layer 111, a second via V2 penetrating the insulating layer 113, and a fourth trace SW14 in the second wiring layer 112. The second redistribution portion 152 is electrically coupled to the fourth redistribution portion 154 through a fifth trace SW15 in the first wiring layer 111, a third via V3 penetrating the insulating layer 113, and a sixth trace SW16 in the second wiring layer 112.

The fifth redistribution portion 155 covers a portion of the surface of the second package layer 14 that is away from the printed circuit board 11, and is adjacent to both the third redistribution portion 153 and the fourth redistribution portion 154. In other words, the fifth redistribution portion 155 extends from the third redistribution portion 153, crossing over the surface of the second package layer 14 that is away from the printed circuit board 11, and then continues to the fourth redistribution portion 154.

The fifth redistribution portion 155 is connected to the first electrode E1 of the high-side transistor HS in each group of transistors 12 through a fourth via V4 penetrating the second package layer 14.

In the above embodiments, in one aspect, the first redistribution layer 15 configured to receive the input signal Vin is exposed on the surface of the power stage package. The first redistribution layer 15 covers portions of two side surfaces of the first package layer 13 and portions of two side surfaces of the second package layer 14. In addition, the first redistribution layer 15 extends from one side surface (i.e., the third side surface S3) of the second package layer 14 to the top surface of the second package layer 14, and further extends to another side surface (i.e., the fourth side surface S4) of the second package layer 14. Thus, the first redistribution layer 15 exposed on the package surface has a larger area, which enhances heat dissipation and helps to further reduce resistance.

In another aspect, the first redistribution portion 151 is connected to the third redistribution portion 153 through the second via V2 penetrating the insulating layer 113, and the second redistribution portion 152 is connected to the fourth redistribution portion 154 through the third via V3 penetrating the insulating layer 113. In this way, the printed circuit board 11 can be regarded as extending laterally, and the first redistribution layer 15 does not extend on the side surface of the printed circuit board 11. When the power stage package is impacted by external force or gripped by automated equipment, even though the side surface of the printed circuit board 11 may be impacted or touched, the first redistribution layer 15 will not be damaged.

Furthermore, the two groups of transistors 12 are integrated into a single power stage package, and each group of transistors 12 includes two stacked transistors, which helps reduce the size of the power stage package.

In some embodiments, the area of the portion of the surface of the second package layer 14 away from the printed circuit board 11 and covered by the fifth redistribution portion 155 is greater than half of the area of the surface of the second package layer 14 that is away from the printed circuit board 11. Thus, the area of the first redistribution layer 15 exposed on the package surface has a larger area, which enhances heat dissipation and helps to further reduce electrical resistance.

In some embodiments, referring to FIG. 3A, the two groups of transistors 12 are arranged along a first direction. The first redistribution layer 15 further includes a sixth redistribution portion 156 and a seventh redistribution portion 157. The sixth redistribution portion 156 is adjacent to the first redistribution portion 151 and extends along the first direction. The seventh redistribution portion 157 is adjacent to the second redistribution portion 152 and extends along the first direction.

The first redistribution portion 151 is sequentially connected to the third redistribution portion 153 through the sixth redistribution portion 156, the third trace SW13, the second via V2, the fourth trace SW14, and the seventh redistribution portion 157. In this case, the connection between the first redistribution portion 151 and the third redistribution portion 153 is more reliable, and the first redistribution layer 15 exposed on the package surface has a larger area, which enhances heat dissipation and helps to further reduce resistance.

In other embodiments, referring to FIG. 3A, the first redistribution layer 15 further includes an eighth redistribution portion 158 and a ninth redistribution portion 159. The eighth redistribution portion 158 is adjacent to the second redistribution portion 152 and extends along the first direction. The ninth redistribution portion 159 is adjacent to the fourth redistribution portion 154 and extends along the first direction.

The second redistribution portion 152 is sequentially connected to the fourth redistribution portion 154 through the eighth redistribution portion 158, the fifth trace SW15, the third via V3, the sixth trace SW16, and the ninth redistribution portion 159. In this case, the connection between the second redistribution portion 152 and the fourth redistribution portion 154 is more reliable, and the first redistribution layer 15 exposed on the package surface has a larger area, which enhances heat dissipation and helps to further reduce electrical resistance.

In yet other embodiments, referring to FIG. 3A, the first redistribution layer 15 includes the sixth redistribution portion 156, seventh redistribution portion 157, eighth redistribution portion 158, and ninth redistribution portion 159. Thus, the connection between the first redistribution portion 151 and the third redistribution portion 153 is more m reliable, as well as the connection between the second redistribution portion 152 and the fourth redistribution portion 154. The first redistribution layer 15 has a larger area exposed on the package surface, which enhances heat dissipation and helps to further reduce electrical resistance.

In some embodiments, referring to FIG. 3A, the first redistribution layer 15 further includes at least one of a tenth redistribution portion 1510 and an eleventh redistribution portion 1511, for example, includes both the tenth redistribution portion 1510 and the eleventh redistribution portion 1511. The tenth redistribution portion 1510 is adjacent to the first redistribution portion 151 and covers a portion of a surface of the first package layer 13 that is away from the printed circuit board 11. The eleventh redistribution portion 1511 is adjacent to the second redistribution portion 152 and covers a portion of a surface of the first package layer 13 away from the printed circuit board 11. This facilitates installation of the power stage package to input the input signal Vin to the first redistribution layer 15. Moreover, the first redistribution layer 15 has a larger area exposed on the package surface, which enhances heat dissipation and helps to further reduce resistance.

In some embodiments, referring to FIGS. 3A and 3B, the power stage package further includes an exposed second redistribution layer 16. The second redistribution layer 16 is configured to receive a ground signal Vgnd. The second redistribution layer 16 covers a portion of a surface of the first package layer 13 away from the printed circuit board 11, and is connected to the second electrode E2 of the low-side transistor LS through a fifth via V5 penetrating the first package layer 13. It should be understood that the second redistribution layer 16 is spaced apart from the first redistribution layer 15.

Thus, both the first redistribution layer 15 and the second redistribution layer 16 are exposed on the package surface, which enhances heat dissipation and helps to further reduce resistance.

In some embodiments, referring to FIGS. 2A and 3B, the power stage package further includes a driver 17 disposed on the second side of the printed circuit board 11 and covered by the second package layer 14.

The driver 17 is connected to a gate G of the high-side transistor HS through a seventh trace SW17 in the second wiring layer 112. Furthermore, the driver 17 is sequentially connected to a gate G of the low-side transistor LS through a sixth via V6 penetrating the insulating layer 113, a seventh via V7 penetrating the first package layer 13, an eighth trace SW18 disposed on a surface of the first package layer 13 away from the printed circuit board 11, and an eighth via V8 penetrating the first package layer 13. For example, the eighth trace SW18 belongs to the second redistribution layer 16.

FIG. 2A also illustrates solder SO at multiple locations. For example, the driver 17 is connected to the seventh trace SW17 through the solder SO; the seventh trace SW17 is connected to the gate G of the high-side transistor HS through the solder SO; the second electrode E2 of the high-side transistor HS is connected to the second trace SW12 through the solder SO; the first electrode E1 of the low-side transistor LS is connected to the first trace SW11 through the solder SO; and so forth.

In some embodiments, referring to FIG. 2A, the power stage package further includes a shielding layer GND located on the surface of the second package layer 14 away from the printed circuit board 11. The shielding layer GND may be configured as ground to reduce adverse effects of external signals on the driver 17. In some embodiments, in a top view, the shielding layer GND completely covers the driver 17 to more effectively reduce the adverse effects of external signals on the driver 17.

In some embodiments, referring to FIG. 2A, the driver 17 in the power stage package may also output other signals through vias penetrating the printed circuit board 11. For example, the driver 17 sequentially outputs current signals flowing through the high-side transistor HS and low-side transistor LS via a ninth via V9 penetrating the printed circuit board 11 and a tenth via V10 penetrating the first package layer 13, for instance outputted via a ninth trace SW19. For example, the ninth trace SW19 belongs to the second redistribution layer 16.

In some embodiments, referring to FIGS. 3A and 3B, the two high-side transistors HS of the two groups of transistors 12 are arranged along the first direction, and the two low-side transistors LS are also arranged along the first direction. The driver 17 and the two groups of transistors 12 are arranged along the second direction perpendicular to the first direction and parallel to the surface of the printed circuit board 11. Such arrangements help reduce the overall size of the power stage package.

In some embodiments, the driver 17 is configured to perform time-division driving of the two groups of transistors 12.

For example, the driver 17 determines two driver signals respectively driving the two groups of transistors 12 according to PWM signals from a control IC. The two driver signals are complementary, meaning that when one driving signal is at a high level, the other signal is at a low level. In some embodiments, the superposition of the two driver signals constitutes the PWM signal from the control IC. The driver 17 drives the corresponding transistor group 12 during the period when the driver signal is at a high level, thus achieving time-division driving of the two groups of transistors 12.

In this manner, a single control IC can be used to drive more transistor groups 12, without being limited by the number of pins of the control IC.

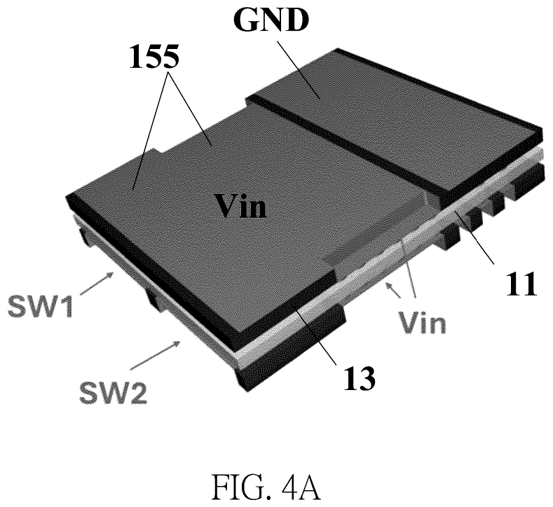

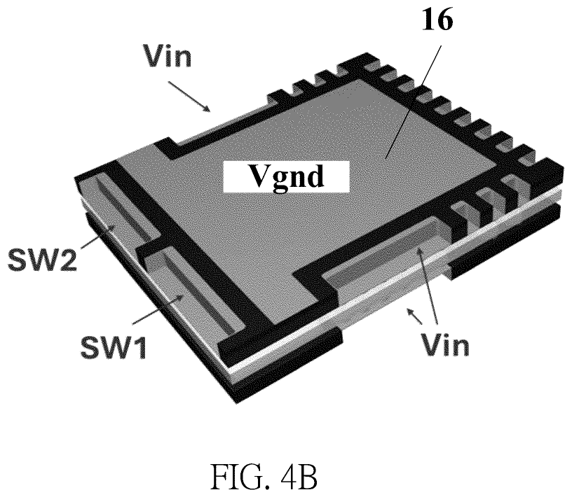

FIG. 4A is a schematic top view illustrating the external appearance of a power stage package according to some embodiments of the present disclosure. FIG. 4B is a schematic bottom view illustrating the external appearance of a power stage package according to some embodiments.

Referring to FIG. 4A, in some embodiments, the fifth redistribution portion 155 of the first redistribution layer 15 may cover a majority of the surface area of the second package layer 14 away from the printed circuit board 11 to improve heat dissipation.

Referring to FIG. 4B, in some embodiments, the second redistribution layer 16 may cover a majority of the surface area of the first package layer 13 away from the printed circuit board 11 to improve heat dissipation.

In some embodiments, the input voltage of the power stage package is in the range of 0.1 V to 100 V, and the output voltage of the power stage package is, for example, in the range of 0.1 V to 100 V.

The present disclosure further provides a voltage regulation module including one or more power stage packages according to any of the above embodiments. In some embodiments, the voltage regulation module further includes a control IC providing PWM signals.

The present disclosure further provides an electronic device including the voltage regulation module according to any of the above embodiments.

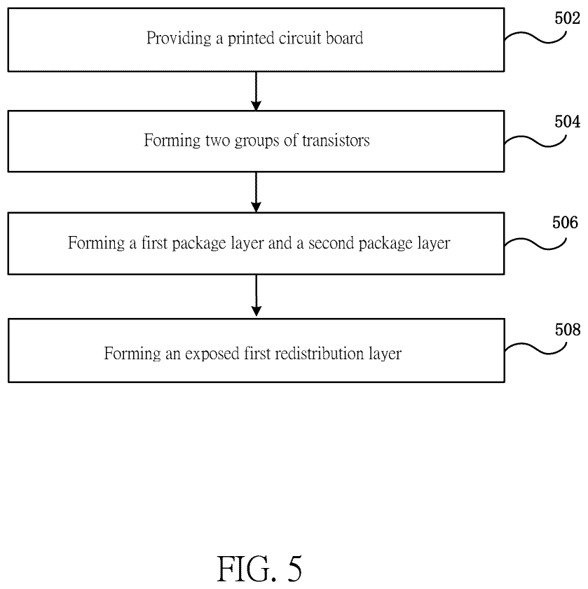

FIG. 5 is a flowchart illustrating a manufacturing method of a power stage package according to some embodiments of the present disclosure.

At step 502, a printed circuit board 11 is provided. The printed circuit board 11 includes a first wiring layer 111, a second wiring layer 112, and an insulating layer 113 disposed between the first wiring layer 111 and the second wiring layer 112.

At step 504, two groups of transistors 12 are formed, each group of transistors 12 includes a low-side transistor LS and a high-side transistor HS.

The low-side transistor LS is located on a first side of the printed circuit board 11, and the high-side transistor HS is located on a second side of the printed circuit board 11 opposite to the first side. The first electrode E1 of the low-side transistor LS is electrically coupled to the second electrode E2 of the high-side transistor HS through a first trace SW11 in the first wiring layer 111, a first via V1 penetrating the insulating layer 113, and a second trace SW12 in the second wiring layer 112.

At step 506, a first package layer 13 and a second package layer 14 are formed.

The first package layer 13 is disposed on the first side of the printed circuit board 11 and covers the low-side transistor LS. The second package layer 14 is disposed on the second side of the printed circuit board 11 and covers the high-side transistor HS. After the formation of the first package layer 13 and the second package layer 14, the aforementioned vias may be formed respectively in the first package layer 13 and the second package layer 14 by laser or the like.

At step 508, an exposed first redistribution layer 15 is formed, which is configured to receive an input signal.

The first redistribution layer 15 includes the first redistribution portion 151, second redistribution portion 152, third redistribution portion 153, fourth redistribution portion 154, and fifth redistribution portion 155 as illustrated in FIG. 3A. The relationships among these portions are described above and will not be repeated here.

In some embodiments, the area of the portion of the surface of the second package layer 14 away from the printed circuit board 11 and covered by the fifth redistribution portion 155 is greater than half of the area of the surface of the second package layer 14 that is away from the printed circuit board 11.

In some embodiments, the formed two groups of transistors 12 are arranged along a first direction, and the formed first redistribution layer 15 further includes the sixth redistribution portion 156 and the seventh redistribution portion 157 as shown in FIG. 3A.

In some embodiments, the formed first redistribution layer 15 further includes the eighth redistribution portion 158 and the ninth redistribution portion 159 as shown in FIG. 3A.

In some embodiments, the formed first redistribution layer 15 further includes at least one of the tenth redistribution portion 1510 and the eleventh redistribution portion 1511 as shown in FIG. 3A.

The connections between the sixth redistribution section 156, the seventh redistribution section 157, the eighth redistribution section 158, the ninth redistribution section 159, the tenth redistribution section 1510, and the eleventh redistribution section 1511 and the other redistribution sections can be referred to as described above

In some embodiments, the manufacturing method of the power stage package further includes forming the exposed second redistribution layer 16 shown in FIG. 3A, which is configured to receive a ground signal.

In some embodiments, the manufacturing method further includes forming a driver 17 located on the second side of the printed circuit board 11 and covered by the second package layer 14. The specific connection between the driver 17 and the gate G of the high-side transistor HS and the gate G of the low-side transistor LS may refer to the aforementioned description.

While various embodiments of the present disclosure have been described in detail. To avoid obscuring the principles and spirit of the present disclosure, certain details well known to those skilled in the art have not been described. It will be readily apparent to those skilled in the art how to implement the technical solutions disclosed herein based on the foregoing descriptions.

Although specific exemplary embodiments of the present disclosure have been described in detail through examples, it should be understood by those skilled in the art that the above examples are only for illustration and not intended to limit the scope of the present disclosure. Those skilled in the art should understand that modifications or equivalent replacements of partial technical features may be made to the above embodiments without departing from the scope and spirit of the present disclosure. The scope of the present disclosure is defined by the appended claims.

What is claimed is:

1. A power stage package, comprising:
a printed circuit board comprising a first wiring layer, a second wiring layer, and an insulating layer disposed between the first wiring layer and the second wiring layer;
two groups of transistors, each group of transistors comprising:
a low-side transistor disposed on a first side of the printed circuit board, and
a high-side transistor disposed on a second side of the printed circuit board opposite the first side, wherein a first electrode of the low-side transistor is electrically coupled to a second electrode of the high-side transistor through a first trace in the first wiring layer, a first via penetrating the insulating layer, and a second trace in the second wiring layer;
a first package layer disposed on the first side of the printed circuit board and covering the low-side transistor;
a second package layer disposed on the second side of the printed circuit board and covering the high-side transistor; and
an exposed first redistribution layer configured to receive an input signal, comprising:
a first redistribution portion covering a portion of a first side surface of the first package layer,
a second redistribution portion covering a portion of a second side surface of the first package layer,
a third redistribution portion covering a portion of a third side surface of the second package layer, wherein the first redistribution portion is electrically coupled to the third redistribution portion through a third trace in the first wiring layer, a second via penetrating the insulating layer, and a fourth trace in the second wiring layer,
a fourth redistribution portion covering a portion of a fourth side surface of the second package layer, wherein the second redistribution portion is electrically coupled to the fourth redistribution portion through a fifth trace in the first wiring layer, a third via penetrating the insulating layer, and a sixth trace in the second wiring layer, and
a fifth redistribution portion covering a portion of a surface of the second package layer away from the printed circuit board, adjacent to the third and fourth redistribution portions, and connected to a first electrode of the high-side transistor in each transistor group through a fourth via penetrating the second package layer.

2. The power stage package of claim 1, wherein the two high-side transistors of the two groups of transistors are arranged along a first direction, and the first redistribution layer further comprises:
a sixth redistribution portion adjacent to the first redistribution portion and extending along the first direction; and
a seventh redistribution portion adjacent to the second redistribution portion and extending along the first direction,
wherein the first redistribution portion is sequentially connected to the third redistribution portion through the sixth redistribution portion, the third trace, the second via, the fourth trace, and the seventh redistribution portion.

3. The power stage package of claim 2, wherein the first redistribution layer further comprises:
an eighth redistribution portion adjacent the second redistribution portion and extending along the first direction, and
a ninth redistribution portion adjacent to the fourth redistribution portion and extending along the first direction,
wherein the second redistribution portion is sequentially connected to the fourth redistribution portion, in order through the eighth redistribution portion, fifth trace, third via, sixth trace, and the ninth redistribution portion.

4. The power stage package of claim 1, wherein the first redistribution layer further comprises at least one of the following:
a tenth redistribution portion adjacent to the first redistribution portion and covering a portion of a surface of the first package layer away from the printed circuit board; and
an eleventh redistribution portion adjacent to the second redistribution portion and covering another portion of a surface of the first package layer away from the printed circuit board.

5. The power stage package of claim 1, further comprising:
an exposed second redistribution layer configured to receive a ground signal, covering a portion of a surface of the first package layer away from the printed circuit board, and connected to a second electrode of the low-side transistor through a fifth via penetrating the first package layer.

6. The power stage package of claim 1, wherein an area of the portion of the surface of the second package layer away from the printed circuit board and covered by the fifth redistribution portion is greater than half of an area of a surface of the second package layer away from the printed circuit board.

7. The power stage package of claim 1, further comprising:
a driver disposed on the second side of the printed circuit board and covered by the second package layer,
wherein the driver is connected to a gate of the high-side transistor through a seventh trace in the second wiring layer, and is sequentially connected to a gate of the low-side transistor through a sixth via penetrating the insulating layer, a seventh via penetrating the first package layer, an eighth trace disposed on a surface of the first package layer away from the printed circuit board, and an eighth via penetrating the first package layer.

8. The power stage package of claim 7, wherein the two high-side transistors of the two groups of transistors are arranged along a first direction, and the driver and the two groups of transistors are arranged along a second direction, the second direction perpendicular to the first direction and parallel to the surface of the printed circuit board.

9. The power stage package of claim 7, wherein the driver is configured to perform time-division driving of the two groups of transistors.

10. A voltage regulation module, comprising the power stage package according to claim 1.

11. A method of manufacturing a power stage package, comprising:
providing a printed circuit board comprising a first wiring layer, a second wiring layer, and an insulating layer disposed between the first and second wiring layers;
forming two groups of transistors, each group of transistors comprising:
a low-side transistor disposed on a first side of the printed circuit board, and
a high-side transistor disposed on a second side of the printed circuit board opposite the first side, wherein a first electrode of the low-side transistor is electrically coupled to a second electrode of the high-side transistor through a first trace in the first wiring layer, a first via penetrating the insulating layer, and a second trace in the second wiring layer;
forming a first package layer and a second package layer, wherein the first package layer is disposed on the first side of the printed circuit board and covering the low-side transistor, and the second package layer is disposed on the second side and covering the high-side transistor; and
forming an exposed first redistribution layer configured to receive an input signal, wherein the first redistribution layer comprises:
a first redistribution portion covering a portion of a first side surface of the first package layer;
a second redistribution portion covering a portion of a second side surface of the first package layer;
a third redistribution portion covering a portion of a third side surface of the second package layer, wherein the first redistribution portion is electrically coupled to the third redistribution portion through a third trace in the first wiring layer, a second via penetrating the insulating layer, and a fourth trace in the second wiring layer;
a fourth redistribution portion covering a portion of a fourth side surface of the second package layer, wherein the second redistribution portion is electrically coupled to the fourth redistribution portion through a fifth trace in the first wiring layer, a third via penetrating the insulating layer, and a sixth trace in the second wiring layer; and
a fifth redistribution portion covering a portion of a surface of the second package layer away from the printed circuit board, adjacent to the third and fourth redistribution portions, and connected to a first electrode of the high-side transistor in each transistor group through a fourth via penetrating the second package layer.

12. The manufacturing method of claim 11, wherein the two groups of transistors are arranged along a first direction, and the first redistribution layer further comprises:
a sixth redistribution portion adjacent to the first redistribution portion and extending along the first direction; and
a seventh redistribution portion adjacent to the second redistribution portion and extending along the first direction,
wherein the first redistribution portion is sequentially connected to the third redistribution portion through the sixth redistribution portion, the third trace, the second via, the fourth trace, and the seventh redistribution portion.

13. The manufacturing method of claim 11, wherein the first redistribution layer further comprises:
an eighth redistribution portion adjacent to the second redistribution portion and extending along the first direction, and
a ninth redistribution portion adjacent to the fourth redistribution portion and extending along the first direction,
wherein the second redistribution portion is sequentially connected to the fourth redistribution portion, in order through the eighth redistribution portion, the fifth trace, the third via, the sixth trace, and the ninth redistribution portion.

14. The manufacturing method of claim 11, wherein the first redistribution layer further comprises at least one of the following:
a tenth redistribution portion adjacent to the first redistribution portion and covering a portion of a surface of the first package layer away from the printed circuit board; and
an eleventh redistribution portion adjacent to the second redistribution portion and covering another portion of a surface of the first package layer away from the printed circuit board.

15. The manufacturing method of claim 11, wherein an area of a portion of a surface of the second package layer away from the printed circuit board and covered by the fifth redistribution portion is greater than half of an area of a surface of the second package layer away from the printed circuit board.
